(19) United States
(12) Patent Application Publication
(10) Pub. No.: US 2012/0218857 A1
(43) Pub. Date: Aug. 30, 2012

(54) MICROFLUIDIC MIXER, METHOD FOR MIXING FLUIDS

(75) Inventors: Leonidas E. OCOLA, Oswego, IL (US); Alexandra JOSHI-IMRE, Richardson, TX (US); Edgar PALACIOS, Chicago, IL (US)

(73) Assignee: UCHICAGO ARGONNE, LLC, Chicago, IL (US)

(21) Appl. No.: 13/407,603

(22) Filed: Feb. 28, 2012

Related U.S. Application Data
(60) Provisional application No. 61/447,576, filed on Feb. 28, 2011.

(51) Int. Cl. B01F 5/06; B81B 1/00

(52) U.S. Cl. 366/336

(57) ABSTRACT

The invention provides a fluid mixer comprising a substrate defining channels having varying widths and depths, wherein the channels have a total mixing distance of from about 50 microns to 1 millimeter. Also provided is a method for mixing fluids, the method comprising: directing a plurality of fluids to a mixing channel having a first width and a first depth; redirecting the directed plurality of fluids to a mixing channel having a second width smaller than the first width and having a second depth greater than the first depth; and repeating the process.

### PRIORITY

This utility application claims the benefits of U.S. Provisional Application No. 61/447,576, filed on Feb. 28, 2011.

### CONTRACTUAL ORIGIN OF THE INVENTION

The United States Government has rights in this invention pursuant to Contract No. DE-AC02-06CH11357 between the United States Government and UChicago Argonne, LLC representing Argonne National Laboratory.

### BACKGROUND OF THE INVENTION

1. Field of the Invention

This invention relates to a method and device to facilitate mixture of fluids, and more particularly, this invention relates to a passive method and device for facilitating mixture of liquids having volumes as little as 1×10⁻⁹ microliters.

2. Background of the Invention

At macroscopic fluid volumes, e.g., greater than 1 milliliter, turbulence is generated easily such that mixing occurs rapidly. This is readily discernable by the naked eye.

Since the advent of the first lab on a chip in the 1980s, microfluidics research has been at the fore, particularly in the fields of medicine and synthetic chemistry. However, at micro scales and below, e.g., 1×10⁻³ liters, viscous forces dominate flow behavior such that fluid behavior becomes more laminar than turbulent. As a result, mixing does not occur, at least not sufficiently compared to the mixing seen at the macroscopic scale.

In order to characterize the flow behavior more quantitatively, two dimensionless numbers are relevant. The first is the Reynolds number (Re). This number defines the flow regime and is defined as the ratio of inertial to viscous forces, these relationships defined in Equation 1 as follows:

Re=(ρVDₕ)/μ Equation 1

where: ρ is the density of the fluid, V is the mean fluid velocity, Dₕ is the hydraulic diameter of the channel, and μ the dynamic viscosity. In microfluidic systems this value usually is <2300 and they are said to be in the laminar flow regime. At values less than 1, stokes flow or creeping motion occurs such that fluids at the walls of the channels tend to stay there and move forward only intermittently. In such laminar flow scenarios, the velocity vectors of the fluid are strictly parallel and have very low momentum. This means that chaotic flow patterns, which would be used at larger scales to induce mixing, cannot be created.

Péclet number (Pₑ)) is another important dimensionless indicator as to which mass transport method is dominating. Péclet numbers quantify the convective transport phenomenon of fluids whereby mixing occurs when two different regions of the same mixture rub against (or otherwise contact) each other. Pₑ is defined as the ratio of advection to diffusion, illustrated in Equation 2 as follows:

Pₑ=(LV)/D Equation 2.

where: L is the characteristic length of the channel, V is the mean fluid velocity and D is the mass diffusion coefficient.

Péclet numbers quantify whether the flow in the system is due to convection or diffusion. If the number is higher it means the system is dominated by advection. A large Péclet number indicates that the fluid transport is occurring due to bulk fluid flow. A small Pₑ indicates that the fluid transport mechanism is governed by diffusion. Therefore, the Péclet number can give an idea of whether mixing is occurring because of diffusion or advection.

Previous microfluidic mixer configurations have utilized helical flow channels in attempts to assure mixing. However, these configurations rely on intersecting flows, making them more difficult to scale down to true micro-fluidic volume processing.

Other designs use counterflow to achieve mixing. However, these systems have narrow channels which clog easily and which do not scale well to accommodate smaller mixture volumes. Rather, such counterflow systems experience high pressure drops. This leads to bottlenecks, with the fluids not passing through the channel.

Microfluidic devices exist comprising separate conduits in different regions of a mixer to accommodate different constituents to be mixed. A porous membrane extending along a common wall of the conduits facilitates mixing of the constituents. These configurations are typical two-dimensional mixers such that all channels are of the same depth. No fluid flow perpendicular to the longitudinal axis of the chambers occurs.

Designs also exist utilizing turn channels arranged perpendicular to diffusion channels. These designs require the fabrication of a bottom and top half of a channel with subsequent precise mating of same. This leads to bulkiness of the final configuration.

A need exists in the art for a fluid mixing system that ensures adequate mixing of liquids and/or gases, despite the low Reynolds numbers seen with typical microfluidic volumes. The system should facilitate liquid and/or gas mixing having a volume as little as 0.1 to 0.5 pico liters, and at fluid mixing lengths of as short as about 70 microns. The system should also be easy to fabricate in that a single work piece defines the fluid flow pattern.

### SUMMARY OF INVENTION

An object of the invention is to provide a microfluidic system that overcomes many of the disadvantages of the prior art.

Another object of the invention is to provide a device to enable thorough mixing of fluids, which in the case of liquids, comprise a total volume of as little as 1×10⁻¹⁵ liters. The fluids can be either charged or uncharged. A feature of the invention is a mixing chamber having varying depths and widths. The varying widths provide a means for inducing lateral flow. An advantage of the invention is a means for imparting lateral velocities to the fluid, thereby enhancing mixing. Another advantage is that varying widths and depths provides a predetermined constant pressure drop across the length of the fluid conduit. This predetermined pressure drop feature (either identical along each of the various segments of the conduit, or not-identical along the segments) provides a means for preventing clogging or fluid build-up at constricting points along the channels. The devices can accommodate fluid volumes from a few sub pico liters to more than 100 microliters.

Yet another object of the present invention is to provide a method for mixing fluids having total volumes of as little as 1×10⁻¹⁵ liters, wherein the fluids are supplied in either batch or continuous mode. A feature of the invention is the utilization of both hydrodynamic mixing and 3-D geometries, wherein the 3-D geometries are based on alternating aspect ratio segments fabricated using micro fabrication techniques, such as ion beam lithography (IBL) and/or 3-D printing. An advantage of the invention is that a passive method for mixing small fluid volumes is established, wherein IBL processes generate mixers having volumes of as small as 1×10⁻¹⁵ liters while 3-D printing processes generate mixers having volumes as small as about 0.5 millimeters.

Still another object of the present invention is to provide a method for fabricating a passive microfluid mixing chamber. A feature of the invention is the use of ion beam lithography to vary the depth of the fluid conduits within the chamber along the longitudinal axis of the chamber. An advantage of the invention is that in the case of ion beam lithography, the fabrication of the conduit occurs in one step, without the need for several layers of molds, or double sided etching processes.

The invention provides a passive fluid mixer (and not an active fluid mixer) comprising a substrate defining channels having varying widths and depths. The invented passive mixers are more efficient that state of the art mixers (i.e., active mixers) in that the invention features a third dimension to mixing, that mixing providing a means for generating lateral and vertical changes in flow. This provides better results than conventional 2D passive mixers or active mixers. The channels in the invented mixers have total mixing distances of less than about 500 microns, preferably less than about 300 microns, and most preferably less than about 100 microns. Embodiments of the device define mixing distances of between about 65 and 75 microns.

The device is relatively compact compared to other mixers inasmuch as no overlay structure exists. Rather, in an embodiment of the invention, the channels are open on the top, with the top openings residing substantially in the same plane. This single, flat top layer design facilitates ease of fabrication in that only a flat, continuously smooth substrate (such as PDMS, glass, quartz, or any other material that can be bonded with the milled monolith) needs to overlay the single machined layer to form the ceiling of the channels. However, the bottoms or floors of the channels reside in different planes.

Also provided is a method for mixing fluids, the method comprising: directing a plurality of fluids to a mixing channel having a first width and a first depth; redirecting the directed plurality of fluids to a mixing channel having a second width smaller than the first width and having a second depth greater than the first depth; and repeating the process.

### BRIEF DESCRIPTION OF DRAWING

The invention together with the above and other objects and advantages will be best understood from the following detailed description of the preferred embodiment of the invention shown in the accompanying drawings, wherein:

FIG. 1 is a schematic of a multi-inlet microfluidic mixer, in accordance with features of the present invention;

FIGS. 2A and 2B are plan and elevation views of fluid flow patterns in the device, in accordance with features of the present invention;

FIGS. 3A and 3B are plan views of flow pressure vectors of binary and cascade device configurations, in accordance with features of the present invention.

FIG. 4 is a photomicrograph of a microfluidic mixer, in accordance with features of the present invention;

FIG. 5 is a plan view of a cascading channel way of a microfluidic mixer, in accordance with features of the present invention;

FIGS. 6A-C are schematics of fabrication techniques of the invented mixer, in accordance with features of the present invention;

FIG. 7A is a photomicrograph of a plurality of microfluidic devices fabricated on a single substrate; and

FIG. 7B is a photomicrograph of a mixing portion of one of the microfluidic devices depicted in FIG. 7A.

### DETAILED DESCRIPTION OF THE INVENTION

The foregoing summary, as well as the following detailed description of certain embodiments of the present invention, will be better understood when read in conjunction with the appended drawings.

As used herein, an element or step recited in the singular and preceded with the word “a” or “an” should be understood as not excluding plural said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

The present invention provides a passive microfluidic mixing device, a method for mixing quantities of fluid below 1 milliliter, and a method for making such devices with conformal surfaces. In this specification, conformal surfaces define seamless surfaces such that no defects are present on the surfaces. The passive (i.e., no moving parts) feature of the invented mixer eliminates the need for power accessories or energy input to create mixing. As such, no mechanical mixing devices, ultra sonic devices, shakers, or other means for physically agitating fluid is employed, other than the static design of the machined mixer container. The mixer itself does not require any external input of energy to mix. Rather, any fluid requiring mixing merely needs to pass through the mixer, which flow can be induced by pressure-driven, osmotic-, capillary- or electrically-driven flow. For example, a pressure drop of about 25 Pa per 5 micron long segment of the mixing chamber (designated herein as element number 30) is suitable. In an embodiment of the invention, this translates into about a 900 Pa pressure drop for the entire device. However, a pressure drop range can be empirically determined and range from approximately 200 Pa (approximately 0.03 pounds per square inch) if larger dimensions of the walls and floors of the mixing chamber are fabricated, to approximately 40 MPa (approximately 5800 psi) for relatively narrower channels and higher flow rates. Other means for inducing flow includes AC and/or DC electrophoresis.

Components of the passive mixing device include varying widths and depths of contiguous segments of mixing channels. A myriad of different dimensions are achievable to define the mixing chamber 30 of the device. Generally, the widths of each section of the mixing chamber 30 can range from between approximately 2 μm and 300 μm, with lengths ranging from a fourth of the width to one-one hundredth the width. Depth measurements will be similar to widths inasmuch as a feature of an embodiment of the invention is to subject the advancing fluid to similar cross sectional shapes (e.g., all squares, all ellipsis, all rectangles, all the same polygonal shape) along the length of the mixing chamber.

Differences in depths between segments are from between approximately 1 to 10 microns. (Prior art devices are relegated to a single depth throughout the channels.) An embodiment of the passive mixer comprises the serial positioning of varying, e.g, alternating, aspect ratio segments as a means to provide a cascade effect of fluid flow. This varying of aspect ratios provides a predetermined pressure drop through the mixer, to thereby induce homogeneous mixing of the mixture being processed.

In an embodiment of the method for making passive microfluidic devices, a single work piece or monolith is machined using focused ion beam direct write lithography (IBL). This provides ease of fabrication and assembly viz assembly of more typical, complex devices. As fluid channel roughness is an important factor when dimensions are below the micron scale, the invented fabrication method creates smooth surfaces with minimal stitching (seam-production) errors. Using a system with an interferometric stage (i.e., a device which uses interference rings to measure positioning of the stage), would be preferred, such as the Raith ionLine (Raith GmbH, Dortmund, Germany), for applications that require high precision pattern placement and minimal stitching errors. The use of such a stage allows smoothing of the final depth of each segment of a channel.

A myriad of materials are suitable substrates for production of monolithic mixers, those materials including but not limited to glass, quartz, plastics, polymers such as lucite, metals such as aluminum and steel, ceramics such as BiFeO₃, BaTiO₃, and other materials such as CoFe/IrMn bilayers, NiFe, Nb, MoGe, and combinations thereof.

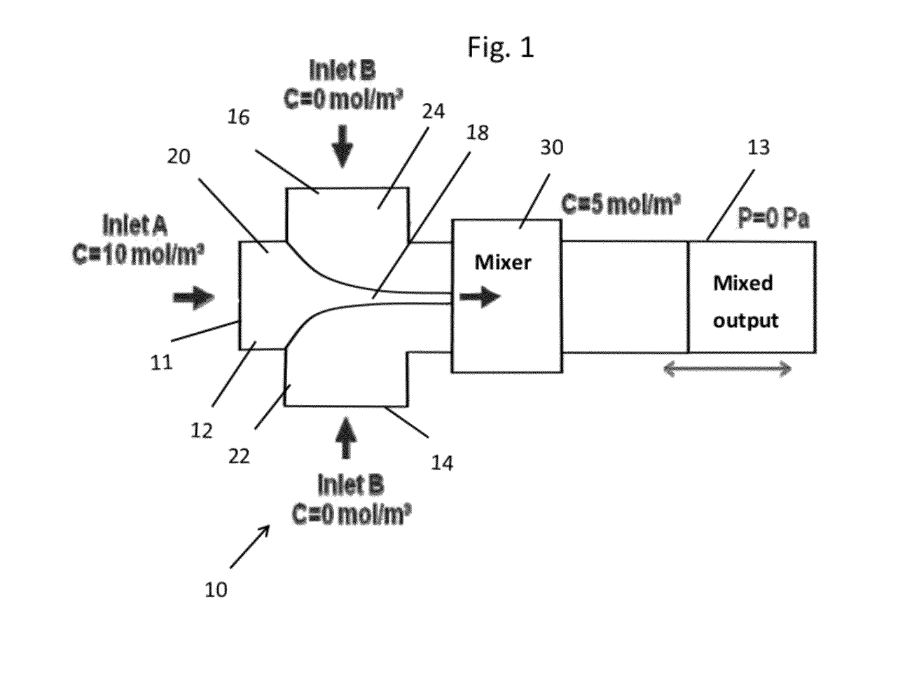

An embodiment of the invention is designated as numeral 10 in FIG. 1. Fluid is shown entering the device from the left of the figures herein. The illustrated embodiment in FIG. 1 comprises three inlet channels 12, 14, 16 forming a T-shaped intersection 18 at the point of a mixer entrance. At the intersection 18, the center flow 20 is squeezed or otherwise constricted by two perpendicular, medially directed sheath flows 22, 24. This inlet setup then creates a concentration gradient on both sides of the center flow, increasing diffusive flux. (An increase n surface area between different fluids results in an increase in diffusion of the fluids into each other.)

The mixer design is made up of five micron segments each with the same pressure drop. The segment pressure drops are calculated using the Darcy-Weisbach equation, depicted as Equation 3, infra:

ΔP=f(LV²)/(Dₕ2g) Equation 3

where f is the friction factor, L is the length of the channel segment, Dₕ is the hydraulic diameter (wherein hydraulic diameter is defines as 2(Length×Width)/(Height+Width)) of the channel segment, V is the mean fluid velocity and g is the acceleration of gravity. By solving the Darcy-Weisbach equation for the depth of a channel segment, the desired pressure drops (e.g. about 1200 Pa per segment) and widths are inputted for all segments of differing widths in order to tune pressure drop gradients and therefore avoid fluid bottlenecks. This pressure drop value would generate a totoal of 60 kPa (8.7 psi) for a 250 micron (μm) long mixer using a flow of about 1 microliter (μL) per minute. A lower pressure limit could be defined using the same mixer dimensions, but with a flow rate of about 0.0001 μL/min (which is the flow rate of a syringe) to yield a pressure drop of about 7.5 Pa/segment for a total pressure drop of 0.735 kPa (about 0.05 psi) In an embodiment where the total mixer length is about 1 mm, a total pressure drop of about 10⁵ Pa is achieved. FIG. 1 shows that while a concentration of a fluid component “C” is 10 mol/cubic meter at the inlet 12, component C is non-existent at inlets 14 and 16. Yet, all components A, B and C are thoroughly mixed at the mixed outpoint point 13 of the invented system.

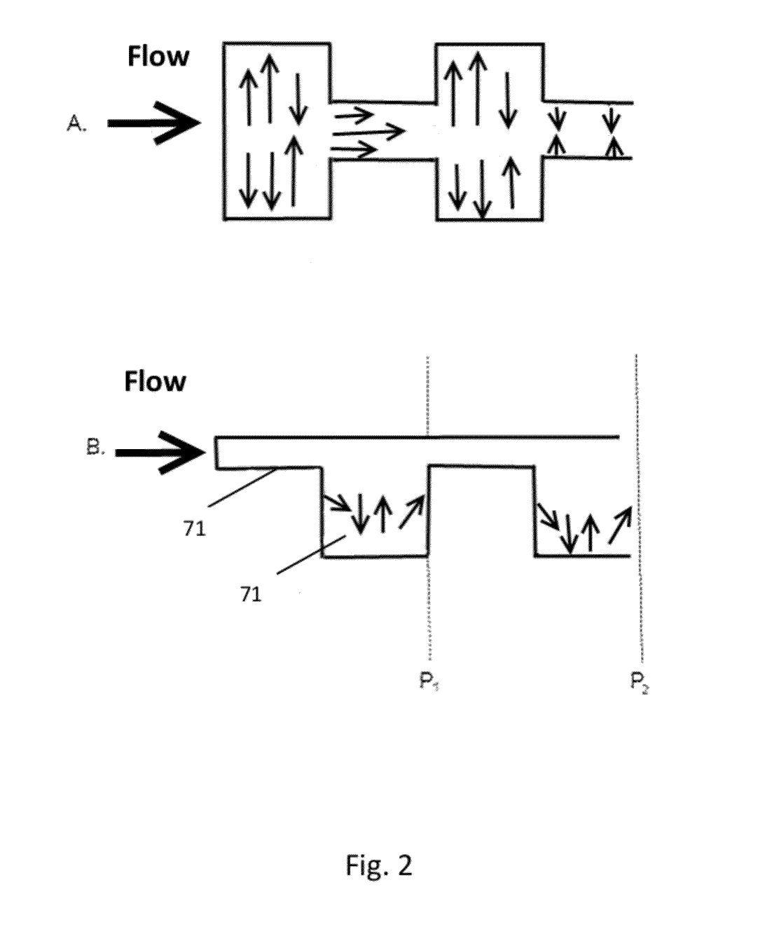

A feature of the mixer is that each subsequent or downstream segment has a different aspect ratio where adjacent segments vary from each other. An example of such variance includes a first segment defining a wide and shallow passage way and a second downstream segment defining a deep and narrow passageway. This variation in dimension can exist in a periodic fashion as seen in FIG. 2. This variation in geometry of the mixer provides a means for dramatically decreasing mixing lengths. Also, the variation in cross section of the conduit channel induces lateral and vertical flow velocities of different magnitudes in the fluid. The different fluid velocities provide a means for enhancing the mixing.

In an embodiment of the invention, the mixing length of the device is no more than about 100 microns, and preferably between about 50 and 75 microns. The invented geometries provide means for inducing lateral velocities to the fluid, those velocities not present in basic diffusion mixers. Aside from inducing lateral velocities, the design enables the establishment of fluid recirculation zones, given high enough Reynolds numbers (e.g., Reynolds numbers greater than one), such that mixing is done even faster. Despite the periodicity featured in the invented device, a constant pressure drop is maintained throughout the mixing length of the channels.

### Example 1

Simulations were run in Comsol Multiphysics™ (Comsul, Inc., Burlington, Mass.) using the Microfluidic Incompressible Navier-Stokes and Convection Diffusion models. The geometries were drawn in Comsol to match the same depth and width parameters of the T-junction and mixer. Suitable parameters include a fluid of density of about 1000 kg/m³ (e.g. 998 kg/m³ was used in the modeling), viscosities of between about 5×10⁻⁴ Pa·s and 1 mPa·s (e.g. 8×10⁻⁴ Pa s and 1.002 Pa s) were used in the modeling) and an isotropic diffusivity coefficient of about 10⁻¹⁰ m²/s. Suitable inlet boundary conditions are about 1 mm/s and 5 mm/s (e.g. 1.1 mm/s was used for the modeling) with a concentration of about 10 mol/m³ for the center flow; about 1 mm/s with a concentration of about 0 mol/m³ for the sheath flows for component A.

In this embodiment, the fluid dynamics are periodic such that the pressure drops are substantially the same throughout the length of fluid travel through the device. FIG. 2B depicts two such periods P1 and P2.

A schematic of boundary conditions can also be seen in FIG. 1.

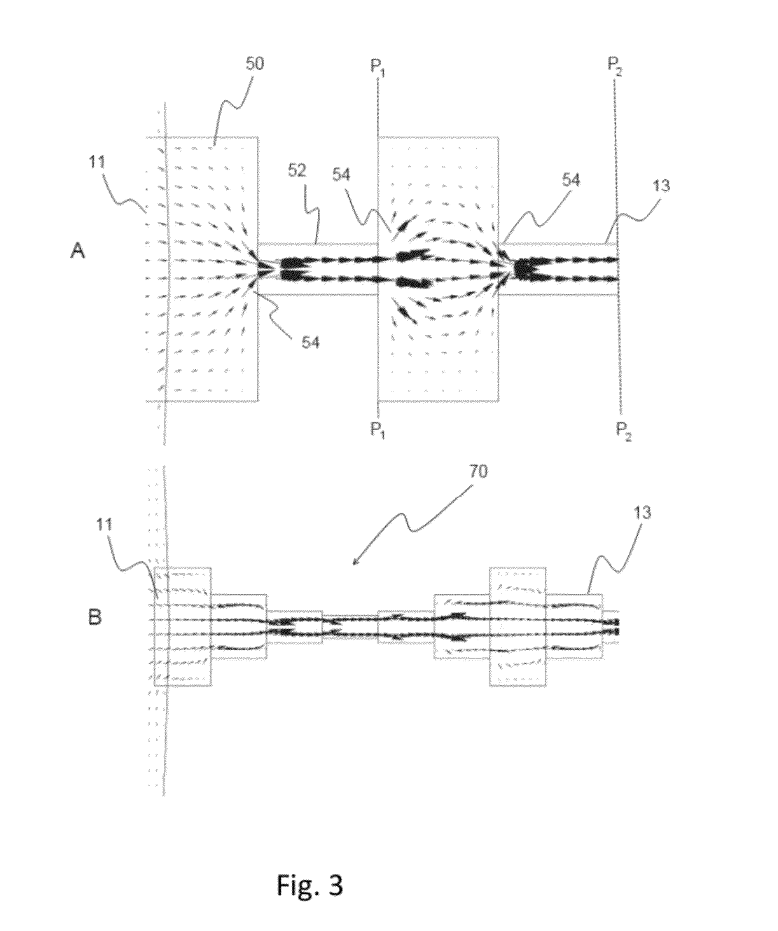

FIG. 3 depicts velocity vector plots of the alternating aspect ratio segments of the mixer. The invented configuration is such that as the fluid travels from wide and shallow segments 50 to narrow and deep segments 52, fluid velocities 54 perpendicular to the bulk of fluid flow are induced. These radially and laterally directed velocities cause a difference in fluid velocities between the center and sheath flows. This difference results in a shearing effect between the two adjacent flows, thereby increasing mixing.

A myriad of different dimensions are achievable to define the mixing chamber 30 of the device. Generally, the widths of each section of the mixing chamber 30 can range from between approximately 2 μm and 20 μm, with lengths ranging from approximately 5 to 10 μm.

The alternating shallow and deeper wells is a means for optimizing heat transfer from the fluid to the bulk of the monolith. For example, an additional feature of this invention is that of heat transfer from the top surface of the mixer and into the fluid during flow. The wide shallow segment allows for large surface area interaction for heat transfer, and the narrow and deep segments allow for improved heat transfer into the cooler monolith substrate.

FIG. 3A depicts a binary fluid conduit configuration, while FIG. 3B depicts a combination binary and cascade configuration. A binary mixer defines one wide and one narrow section. A cascade mixer is comprised of multiple binary segments arranged collinearly with each other so as to form an extended fluid conduit.

The invented configuration creates velocity vectors which converge laterally as the fluid goes from wide to narrow and diverge radially as the fluid goes from narrow to wide. The velocity vectors converge laterally and diverge vertically as the fluid goes from wide to narrow. As the fluids go from narrow to wide they converge vertically and diverge laterally. The velocity vector behavior is effected by the change in aspect ratio of adjacent sections in the mixer. The vectors are a function of the depth of the conduit, the aspect ratio of those segments, and the sequence of those segments. The vectors are effected by the depths and widths of the mixer due to the fluid conforming to the sides of the conduit. For example, FIG. 3A features abrupt changes from wide and shallow segments to narrow and deep ones. FIG. 3B depicts a configuration having more gradual changes between segments. The abrupt changes provide a means for inducing stronger perpendicular velocity vectors, (i.e., more forceful laterally- and medially-directed pressure) to the fluid.

In a binary configuration, depicted as numeral 60 in FIG. 3A, starting upstream, fluid enters the device. Proximal to the means of fluid ingress of the device is situated the wide, shallow region 50. Downstream, and in fluid communication with the shallow region is the relatively narrow deep region 52. This binary configuration represents one period P1. Following this first period is a repeat period P2 of the entire binary configuration.

A binary-cascade configuration is depicted in FIG. 3B as numeral 70. This configuration defines a wide shallow flow-way at a proximal end 11 (proximal relative to the inlet stream position) and a narrower, deeper flow-way at a distal end 13. Intermediate the proximal and distal ends is a plurality of co-linearly positioned conduits the diameter of each conduit within that plurality different from flanking conduits (i.e., those flanking conduits being defined herein as being immediately adjacent to the above each conduit so as to be in direct contact with the ends of the above each conduit).

The binary-cascade configuration 70 defines a flow-way which starts wide and shallow at its proximal end, then deep and narrow, then wide and shallow again. In an embodiment of the invention, the flow-way comprises a plurality of segments, the segments contiguous with each other so as to be in fluid communication with each other. The floors 71 of these segments, while contiguous, vary in depth from each other. Embodiments of the invention comprise flat floors and nonflat floors. Flat floors provide a means for preventing local vortices or the trapping of any vortices which develop during the mixing process. Non-flat floors (e.g., conduits which have varying floor heights along the length of the conduits) also provide a means for eliminating traps which otherwise collect detritus and other material, leading to clogging of the fluidic channel. Also, sections of the non-flat floors can also result in local vortices occurring.

The repeating widening and narrowing of the flow-way seen in FIG. 3B induces more thorough mixing compared to the binary flow-way depicted in FIG. 3A. The “repeating” configuration has been referred to herein as alternating aspect ratio segments.

Other configurations are also suitable, including curved flow-ways, spiral-shaped flow-ways, and combinations of curved and straight flow-ways.

A more quantitative view of the invented mixer characteristics is seen in Table 1. Table 1 provides the pressure drop, Reynolds number, Péclet number and mixing length of straight, binary and cascade mixers. Unlike typical straight mixer configurations, the invented binary and cascade mixer pressure drops are close to expectation ˜10⁴ Pa. The Reynolds numbers are <1 indicating laminar flow. Despite such low Reynolds numbers (and the concomitant laminar flows associated therewith), the invented device thoroughly mixes the constituents of the mixture.

The higher Péclet numbers correlate to the shortening in mixing lengths. For example, referencing the straight mixer, mixing lengths were at least >160 μm with a maximum Péclet number of 93. For both the invented binary and cascade designs, the mixing lengths dropped to ˜70 μm with Péclet numbers values of 550 and 240 respectively. The invented system's transport is mainly due to the bulk fluid flow. Higher Péclet numbers shown herein confirm the relatively higher mixing efficiencies of the invented systems.

The low Reynolds numbers, high Péclet numbers and short mixing lengths reveals that the increased mixing efficiency is not due so much to lateral velocities but to the shearing effect between the center and adjacent flows. As such, the invented device and method provides substantially complete mixing without the need of intersecting flows and intersecting conduits. Rather, mixing occurs via shearing forces.

TABLE 1
Comparison of Flow Characteristics for Miscellaneous Mixers

| | | | | Mixing |
|---|---|---|---|---|
| | Pressure | | | Length |
| Shape | (Mpa) | Max Re | Max Pe | (μm) |
| Straight | 0.26 | 5.00E−04 | 93 | >200 |
| Binary | 0.101 | 0.060 | 550 | ~70 |
| Cascade | 0.366 | 0.026 | 240 | ~80 |

### Fabrication

### Example Detail

The fabrication of the devices involves two phases. The first phase is the fabrication of the inlet and outlet channels using standard optical lithography. The substrates used were quartz of 0.5 mm thickness. After cleaning in ultrasonic with Acetone for about 5 minutes, a suitable layer of inert metal is deposited on the quartz substrate. In an embodiment, approximately 200 nm of Chromium is deposited on the quartz substrate.

The now coated substrate is then spun coated with S1813 negative resist at 3000 rpm and baked for approximately 1 minute at about 110° C. A direct contact exposure was effectuated using a Karl Suss MA6 UV lithography tool for approximately 16 seconds with a Cr mask. The image was developed in a solution of 4:1 ratio of deionized water to Microposit 351 developer (available from Shipley Company, Marlborough, MA) for approximately 40 seconds. The Cr was then etched via Cr wet etch for 2 minutes followed by the quartz etch. The first step in the quartz etch is a dry etch using a Oxford Plasmalab 100 RIE system for 1 hour. The recipe used is: 55 sccm of CHF₃ and “25.1×2 sccm of O₂ with a forward power of 250 W at 20° C. After about 1 hour of RIE, the device is wet etched in approximately a 10:1 buffered oxide etch (BOE) for a time suitable to eliminate micromasking effects. (Ten minutes was typical.) These two etching steps are repeated (with subsequent RIE steps lasting about 10 minutes) to reach a channel depth of 10 μm.

The second phase of the fabrication is the IBL of the micromixer. The IBL tool used is a FEI NovaLab 600 equipped with a 100 nm resolution stage, a Raith Elphy Lithography Interface and a 16-bit pattern generator. The mixer design was loaded on a computer aid design (CAD) file in GDS II format. IBL offset patterning and multiple GDS cell copy techniques were utilized to fabricate the mixers. These techniques are disclosed in A. Imre, L. E. Ocola, L. Rich, J. Klingfus, J. Vac. Sci. & Technol. B, 28, 304, (2010), and also and incorporated herein by reference.

Exposures were run using an ion beam current of about 3 nA, a 30 kV accelerating voltage and base dose of 600 μC/cm² per pass. The milling depth in quartz for a single pass was measured to be 1.32 nm. This value was determined by exposing arrays of boxes with different number of passes followed by atomic force microscopy metrology. Once the calibration is done, the milling depth per pass can be used to calculate the number of GDS structure copies required for a specific design depth.

In the case for quartz and exposure conditions described above, the total depth equals the number of copies (at 1.32 nm per copy).

Instead of just assigning the total number of passes to each segment, a common depth approach can be utilized. For example, an embodiment of the mixer cell comprises 4 sub-cells. Since some of the mixer segments are deeper than others, the sub-cells contain segments of the mixer which are deeper than the shallowest segment in the sub-cell. This way, groups of segments are exposed together to help minimize redeposition effects by milling areas of common depth first and then areas that were deeper milled later. Table 2 shows the number of passes in each sub-cell in the fourth column along with the corresponding depths and widths of each segment.

Due to the non-conductive nature of quartz, charging is a problem when using IBL. In order to reduce the charging effects so that IBL patterning is not affected, the Cr is not removed and about 10 nm of Espacer™ is spun coated on top of the sample. Once the IBL mills past the Espacer and Cr, the quartz is exposed. A charge neutralizer beam is utilized to flood the same with positive charge to eliminate additional charging effects. Suitable flood conditions are 130 nA and 170 eV.

TABLE 2
Correlation between width, depth and ion beams exposures

| Width | Total Depth | Total Depth | Differential Depth |
|---|---|---|---|
| (μm) | (μm) | (# of passes) | (# of passes) |
| 11 | 1.2 | 1.2 | 919 |
| 6 | 1.6 | 1.6 | 1231 |
| 3 | 2.7 | 2.6 | 2020 |
| 2.1 | 4 | 4 | 3032 |

Because of the nature of IBL and large patterning area, offset patterning is used to mitigate redeposition, and stitching errors. Offset patterning mitigates redeposition and stitching errors by no longer having the write fields meet at the same edge. First, the gds file is manipulated by duplicating the mixer cell five times each with one-fifth the number of total copies for each mixer segment. These five cells are then offset in the x and y coordinates where x and y are parallel and perpendicular to the mixer respectively. Loading the gds file into the Raith Elphy lithography interface creates a position list which moves the 100 μm write field equal to the offset that was placed in the gds file cell. This enables all five cells to fall on top of each other.

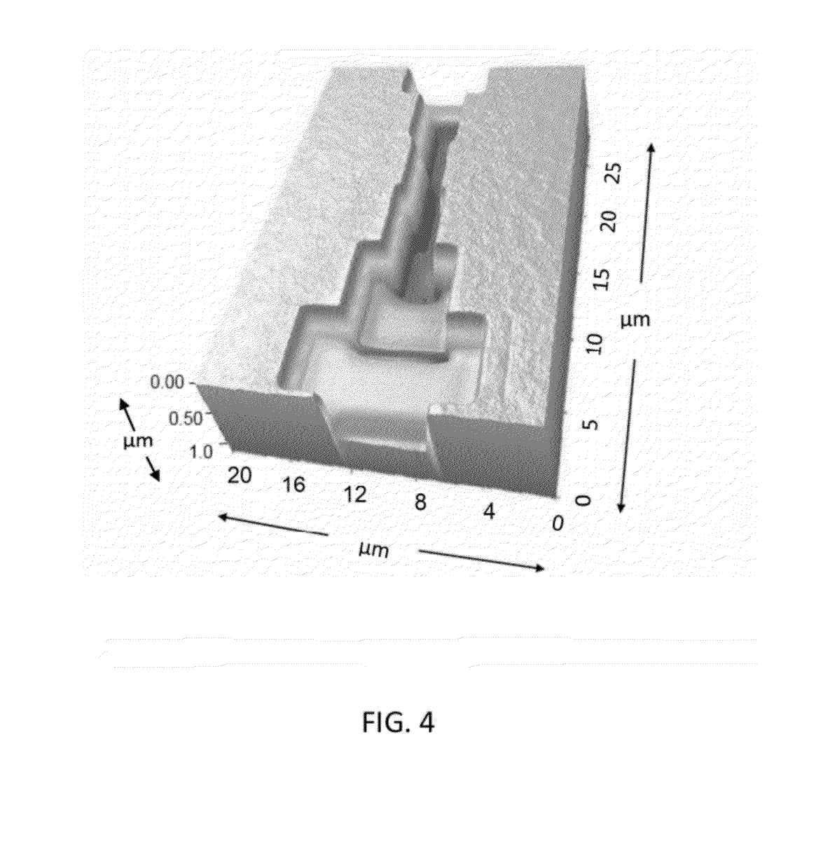

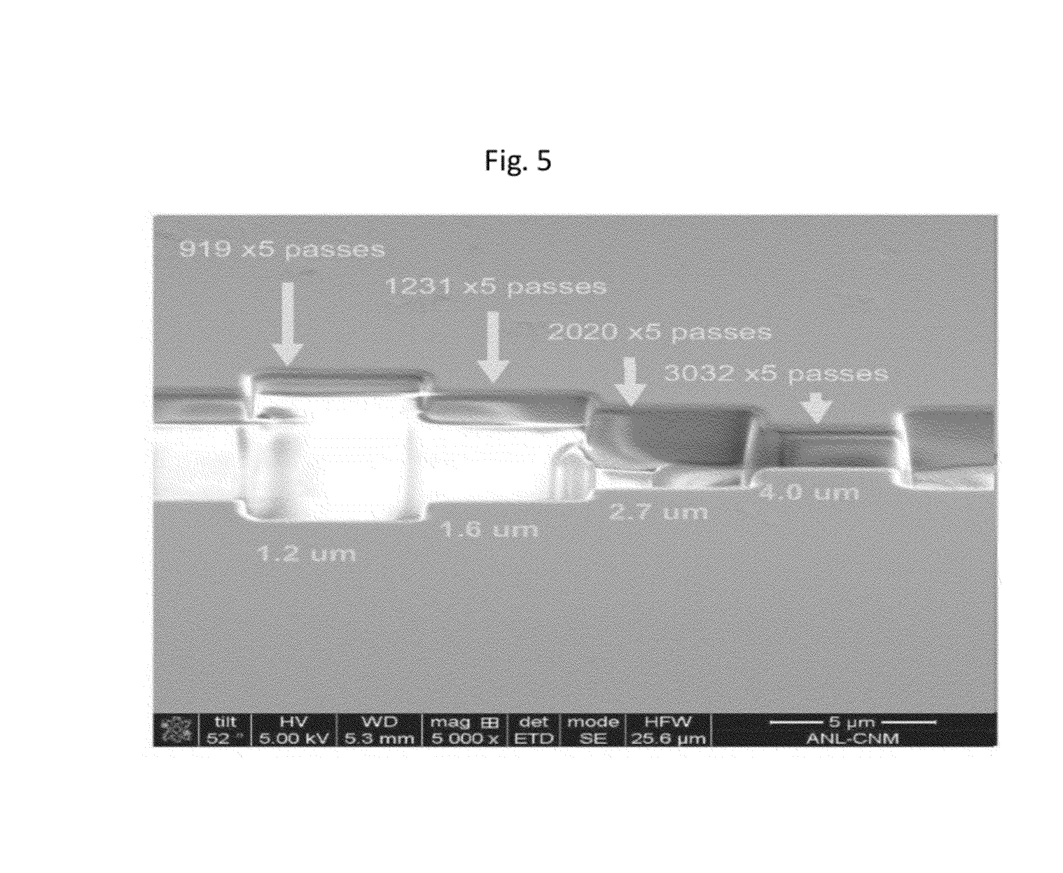

The combination of offset patterning, and common depth approach in gds file sub-cells mitigates the stitching errors and redeposition effects. FIGS. 4 and 5 reveal the bottom surface of the mixer segment being level. The longitudinal axes of each of the segments of the channel in this embodiment are co-linear. The lower numbers in FIG. 5 (which is a plan or aerial view) designate the depth of the channel at that point. The upper numbers designate the number of scans an ion beam made to generate that segment of the channel. For example, the designation “919×5 passes” indicates that a total of 4595 scans (i.e. 919×5 scans) were required to achieve a depth of 1.2 microns. That depth was reached when 5 offset positions were each treated with 919 scans for that segment of the mixer. The offsetting is necessary to eliminate seams or ridges which would otherwise develop between floor segments and within the same floor segment due to shard deposition, as discussed below.

In an embodiment of the invented method of fabrication of microfluidic channels, an entire channel is first scanned to one fifth of the depth of the shallowest segment of the channel. Then, the field of view of the scanner is repositioned along the longitudinal axis of the channel such that the newly positioned field of view slightly over laps the first field of view. The entire channel is rescanned to two fifths of the depth of the shallowest segment. After the two-fifths depth is realized, the field of view of the scanner is again repositioned along the longitudinal axis of the channel.

This overlapping process is continued until the target depth of the most shallow segment of the channel is achieved, at which point the next shallow segment depth is milled in a similar protocol. The repositioning of the stage (which supports either the ion beam lithography gun or the work piece), eliminates the potential of aberrations forming along the floor of the channel, said aberrations formed by a redeposition of “filings” which are generated during scanning. The offset scanning protocol also prevents seams (which otherwise define the abutting edges of fields of view) from developing. The aforementioned embodiment, the results of which are depicted in FIG. 5, proves that the multi-pass/low dose technique provides a means for eliminating redeposition. It also provides a means for eliminating stitching errors. With the stage being used in the IBL tool, stitching errors were not visible in the cascade mixer.

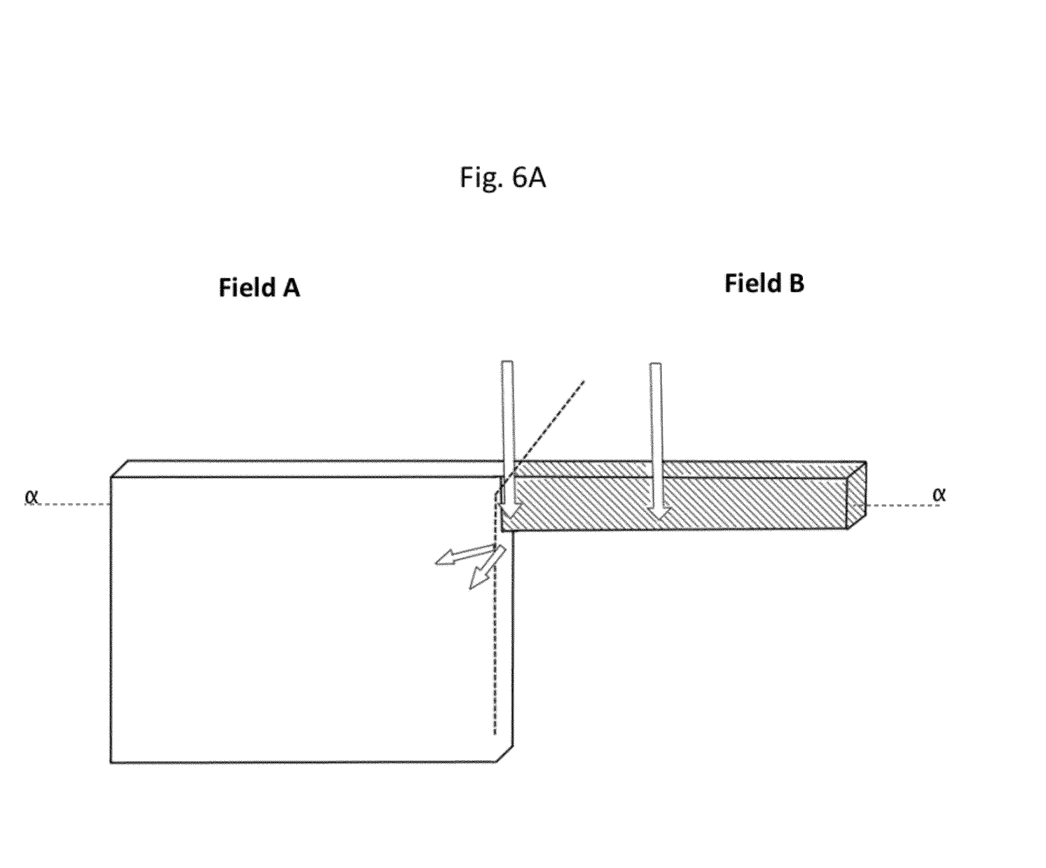

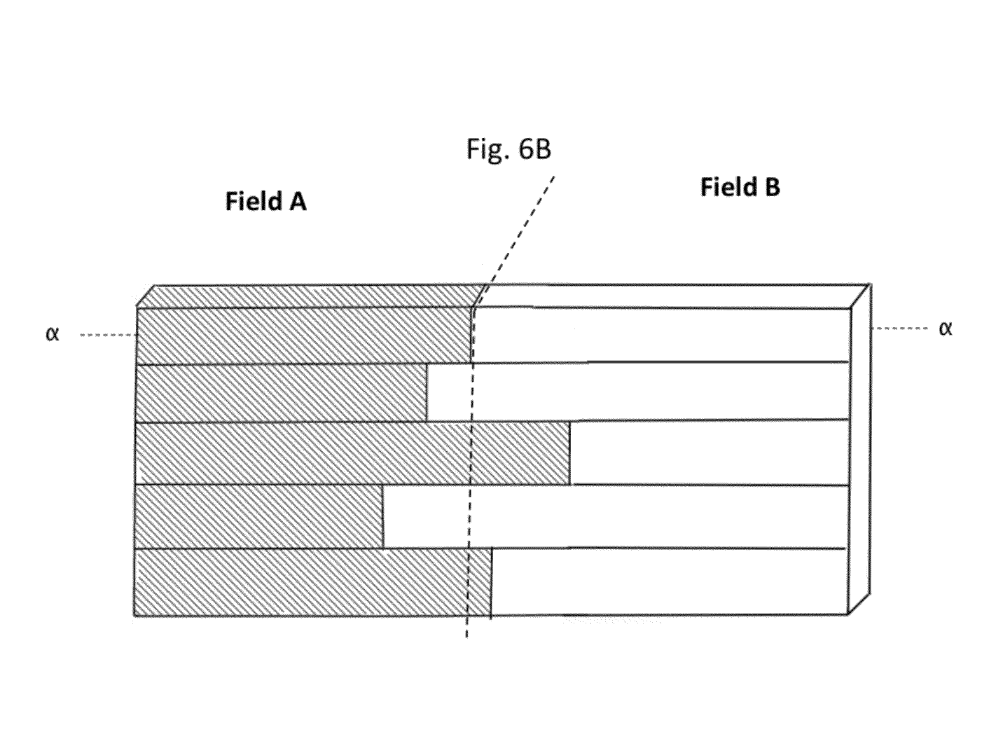

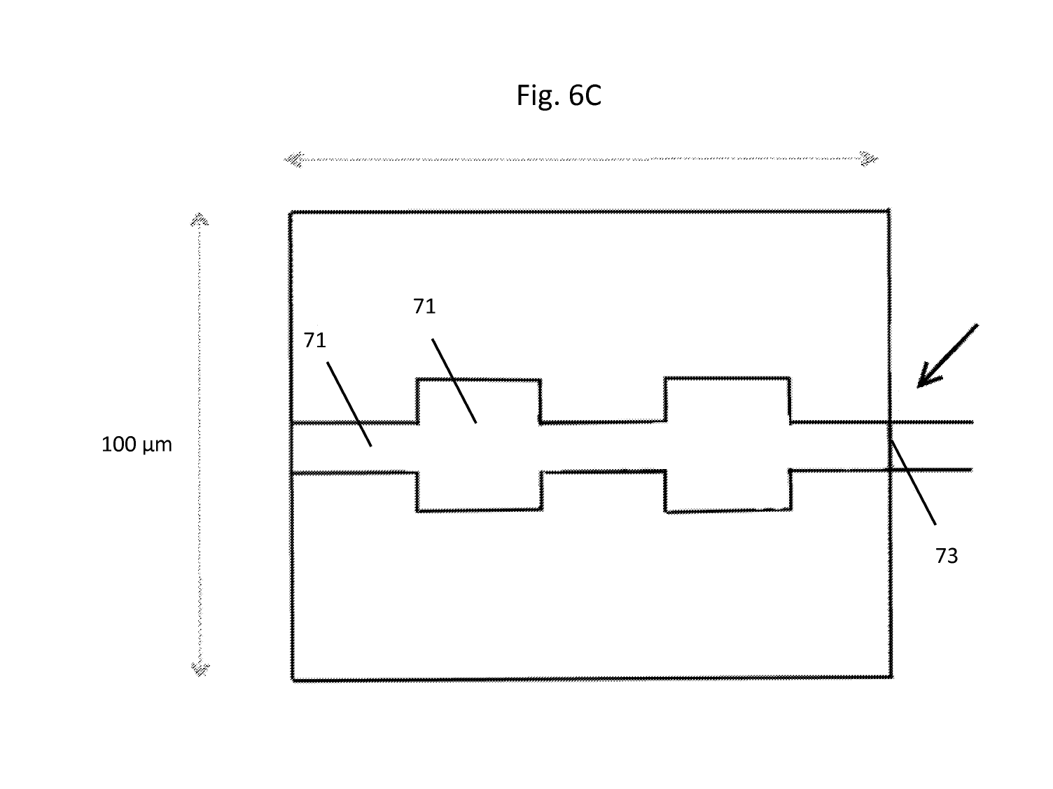

This fabrication process is schematically depicted in FIGS. 6A-C. FIG. 6A, which is an elevation of two adjoining (designated by the dotted line) segments of a channel, shows redeposition (downwardly extending arrows) of milling shards between IBL fields A and B. In this scenario, shards from field B fall into and resolidify in regions of field A. To eliminate this redeposition effect, the fields are moved along the longitudinal axis a of the channel way during the lithography process, as depicted in FIG. 6B. This repositioning of the scan field results in deposited shards being revaporized or otherwise smoothed out over the resulting floor of the channel being fabricated.

FIG. 6C is a plan view of the invented binary mixer in fabrication. In this view, an IBL field of view is 100 microns square. As the arrow designates, portions of the workpiece outside the field of view are not milled by the IBL gun. When those portions finally are milled, inadvertent misalignment between IBL scanning applications results in transversely extending seams in the floor 71 of the channel way.

After fabrication of the mixer, the Espacer and Cr is removed from the substrate. Both the substrate and PDMS mold are treated with an oxygen plasma treatment, aligned and bonded.

In operation, a completed 3D microfluidic mixer is first tested for leaks and prepped for a mixing experiment. The experiment consisted of mixing two liquids with different pH (pH=2, pH=8). The liquid with pH=8 was loaded with a Fluorescein fluorophore. The fluorescence of Fluorescein is pH dependent. Therefore upon mixing with a liquid with pH=2 the fluorescence intensity dropped dramatically.

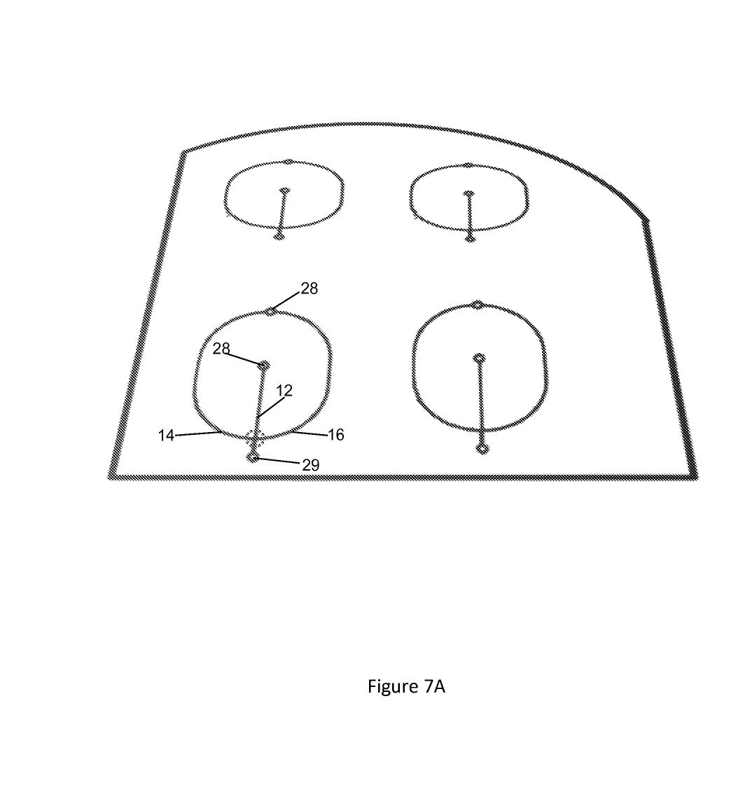

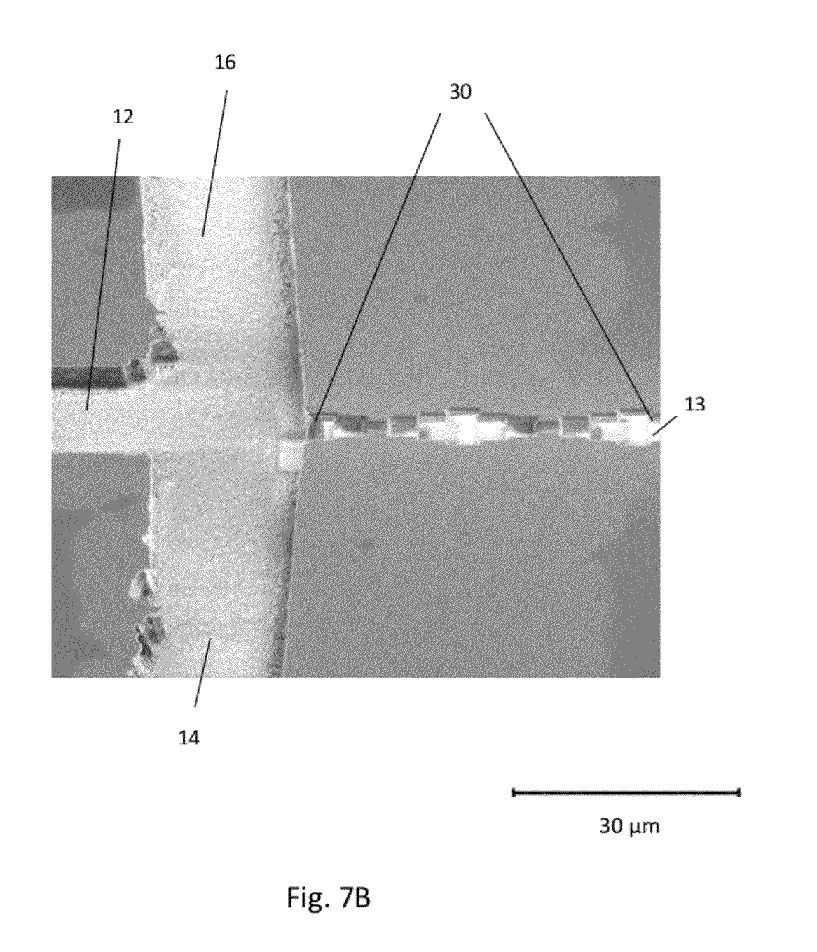

As discussed supra, an embodiment of the mixer is monolithic in design such that fluid ingress and egress portals are integrally molded with conduits leading up to the mixing chamber 30 and away from the mixing chamber. This embodiment can be homogenous in construction such that it is comprised of substantially one material. FIG. 7A depicts a plurality of microfluidic processors fabricated on a single waver of silicon. Aside from silicon, other suitable materials include quart, glass, plastics, polymers, ceramics, metals, and combinations thereof. The embodiment can be replicated by standard molding, injection molding, and other 3D fabrication techniques such as 3D printing.

The silicon substrate seen in FIG. 7A supports 4 mixing modules, in effect defining a miniature refinery have a plurality of discrete mixers which can be operating simultaneously, serially, or in parallel.

FIG. 7B is an enlarged view that portion of the lower left module in FIG. 7A that is circumscribed by a circle. Each of the modules in FIG. 7A comprise the fluid feed conduits 12, 14, and 16, and the mixing chamber 30 which is situated downstream of the feed conduits. Also depicted in each of the modules is a plurality of fluid portals 28 which provide a means for introducing fluid into the fluid feed conduits. As such, the fluid portals are in fluid communication with the feed conduits. A final mixture harvesting portal 29 is provided to remove the mixed fluid from the module. These portals can be of any geometric configuration. An embodiment of the invention defines a cylindrically shaped portal having a circular opening. The cylinder extends substantially through the substrate and is produced by etching substantially through the substrate so that the portal can be accessed from both sides of the substrate. Alternatively, the cylinder extends to a depth of the substrate so as to establish fluid communication with the fluid supply conduits which are also defined by regions of the substrate. Optionally, the ceiling of the conduits are hermetically sealed or otherwise isolated from the ambient atmosphere by an overlayment on the substrate. The overlayment, which would prevent fluid communication between the conduits and the atmosphere, can consist of identical or similar material to the substrate and may or may not be transparent, radio lucent, or a combination thereof. In this embodiment of the invention, a fluid feed stream supply portal is attached to the periphery or rim of the portal so as to produce a hermetic seal. For example, a distal end of a syringe loaded with a fluid is epoxied or otherwise adhered to the portal opening.

FIG. 7B is an actual embodiment of the schematic diagram offered in FIG. 1, and more clearly illustrates how the mixing chamber 30 is integrally molded with the fluid feed conduits 12, 14, and 16.

Optionally, a conduit (or a plurality of conduits) is further machined into the substrate to facilitate contact and or treatment of the mixing fluid with electromagnetic or particle bombardment, those particles including subatomic particles such as photons, neutrons, protons and electrons. The conduits can intersect the mixing chamber 30, or intersect the fluid feed conduits 12, 14, and 16 or intersect with the mixed fluid output 13. The radiation and or electrons would serve to either pretreat a fluid component prior to it being mixed, treat the fluid simultaneous with mixing operations, and/or to treat the already mixed fluid components. Other additions include electronic components which allow for sensing or fluid manipulation. These components could be either integrally molded or reversibly attached to the mixer.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting, but are instead exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the terms “comprising” and “wherein.” Moreover, in the following claims, the terms “first,” “second,” and “third,” are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” “more than” and the like include the number recited and refer to ranges which can be subsequently broken down into subranges as discussed above. In the same manner, all ratios disclosed herein also include all subratios falling within the broader ratio. One skilled in the art will also readily recognize that where members are grouped together in a common manner, such as in a Markush group, the present invention encompasses not only the entire group listed as a whole, but each member of the group individually and all possible subgroups of the main group. Accordingly, for all purposes, the present invention encompasses not only the main group, but also the main group absent one or more of the group members. The present invention also envisages the explicit exclusion of one or more of any of the group members in the claimed invention.

The embodiment of the invention in which an exclusive property or privilege is claimed is defined as follows:

1. A fluid mixer comprising a substrate defining channels having varying widths and depths, wherein the channels have a total fluid mixing distance of less than 100 microns.

2. The mixer as recited in claim 1 wherein the substrate is integrally molded with fluid ingress and egress conduits.

3. The mixer as recited in claim 1 adapted to receive a fluid having a density of about 1000 kg/m³.

4. The mixer as recited in claim 1 wherein the channels have substantially flat floors.

5. The mixer as recited in claim 1 wherein the channels are substantially straight.

6. The mixer as recited in claim 1 further comprising a flat substrate overlaying the channels.

7. The mixer as recited in claim 1 wherein some of the channels are wide and shallow compared to other channels.

8. The mixer as recited in claim 7 wherein some of the channels are narrow relative to the wide channels and the wide channels are more shallow than the narrow channels.

9. The mixer as recited in claim 1 wherein said channels are in fluid communication with each other.

10. The mixer as recited in claim 1 wherein the channels are co-linear with each other and no obstructions exist within said channels.

11. The mixer as recited in claim 2 wherein the mixer, the ingress and egress conduits are formed on a monolith.

12. A method of mixing fluids, the method comprising:
a. directing a plurality of fluids to a mixing channel having a first width and a first depth; and
b. redirecting the directed plurality of fluids to a mixing channel having a second width smaller than the first width and having a second depth greater than the first depth; wherein the channels have a total mixing distance of more than about 50 microns and less than about 100 microns.

13. The method as recited in claim 12 wherein steps a and b are repeated.

14. The method as recited in claim 12 wherein fluid is subjected to a constant pressure drop throughout the total mixing distance.

15. The method as recited in claim 12 wherein the fluids are subjected to laterally directed force when directed to said first widths and are subjected to a medially directed force when subjected to said second widths.

16. The method as recited in claim 12 wherein the fluids are pressurized.

17. The method as recited in claim 12 wherein the fluids are charged.

18. The method as recited in claim 12 wherein the mixing channel defines a means of ingress for charged particles to enter the channel.
